(19) United States
(12) Patent Application Publication
(10) Pub. No.: US 2013/0264107 A1
(43) Pub. Date: Oct. 10, 2013

(54) CIRCUIT BOARD AND WIRE ASSEMBLY

(71) Applicant: Joel Nathan Meyers, Middletown, PA (US)

(72) Inventor: Joel Nathan Meyers, Middletown, PA (US)

(73) Assignee: TYCO ELECTRONICS CORPORATION, Berwyn, PA (US)

(21) Appl. No.: 13/461,503

(22) Filed: May 1, 2012

Related U.S. Application Data
(60) Provisional application No. 61/620,761, filed on Apr. 5, 2012.

(51) Int. Cl. H05K 1/00

(52) U.S. Cl. 174/268

(57) ABSTRACT

A circuit board includes a substrate extending from a mounting end to an opposite end. The substrate extends a thickness from an upper side to a lower side. The substrate includes a recess that extends into the mounting end in a direction toward the opposite end. The circuit board includes an internal ground plane held by the substrate such that the internal ground plane extends within the thickness of the substrate. The internal ground plane includes a recess segment that extends, and is exposed, within the recess.

This application claims priority benefit from U.S. Provisional Application Ser. No. 61/620,761, which was filed on Apr. 5, 2012, and is titled “CIRCUIT BOARD AND WIRE ASSEMBLY”. The entire disclosure of the 61/620,761 Application is incorporated by reference herein.

The subject matter described and/or illustrated herein relates generally to circuit boards, and more particularly, to circuit boards that terminate electrical wires.

### BACKGROUND OF THE INVENTION

Electrical wires are sometimes used to electrically connect electrical components to circuit boards. Specifically, ends of such electrical wires may be terminated to the circuit board to electrically connect the circuit board to an electrical component that terminates the opposite ends of the electrical wires. Such electrical wires may be individual electrical wires, or two or more electrical wires may be grouped together in a cable. One example of a circuit board that terminates electrical wires is a circuit board of an electrical connector.

Competition and market demands have continued the trend toward smaller and higher performance (e.g., faster) electronic systems. But, the signal paths within such smaller and higher performance electronic systems may interfere with each other, which is commonly referred to as “crosstalk”. One source of crosstalk is the wire mount area where electrical wires are mounted to contact pads of a circuit board, for example using solder. For example, differential pairs of electrical wires that are mounted to an upper side of the circuit board may experience crosstalk with differential pairs of electrical wires that are mounted to a lower side of the circuit board. Such crosstalk can become a relatively large contributor to errors along the signal paths of the electrical wires and/or the circuit board.

There is a need for a circuit board and wire assembly that experiences less crosstalk between electrical wires that are terminated to the circuit board.

### BRIEF DESCRIPTION OF THE INVENTION

In one embodiment, a circuit board includes a substrate that extends from a mounting end to an opposite end. The substrate extends a thickness from an upper side to a lower side. The substrate includes a recess that extends into the mounting end in a direction toward the opposite end. The circuit board includes an internal ground plane held by the substrate such that the internal ground plane extends within the thickness of the substrate. The internal ground plane includes a recess segment that extends, and is exposed, within the recess.

In another embodiment, a circuit board and wire assembly includes upper and lower electrical wires having insulating members and electrical signal conductors that include exposed end segments that extend lengths outward from the insulating members. The assembly also includes a circuit board having a substrate extending a thickness from an upper side to a lower side. Upper mounting pads extend on the upper side of the substrate. The exposed end segments of the upper electrical wires are terminated to the upper mounting pads. Lower mounting pads extend on the lower side of the substrate. The exposed end segments of the lower electrical wires are terminated to the lower mounting pads. An internal ground plane is held by the substrate such that the internal ground plane extends within the thickness of the substrate. The internal ground plane extends between the exposed end segments of the upper electrical wires and the exposed end segments of the lower electrical wires along an approximate entirety of the lengths of the exposed end segments of the upper and lower electrical wires.

In another embodiment, a circuit board is provided for terminating electrical wires having insulating members and exposed end segments that extend lengths outward from the insulating members. The circuit board includes a substrate extending from a mounting end to an opposite end. The substrate has a side that includes a mounting region. The substrate extends a thickness from the side to an opposite side. Mounting pads extend on the side of the substrate within the mounting region. An internal ground plane is held by the substrate such that the internal ground plane extends within the thickness of the substrate. The mounting region of the substrate is offset along the mounting end in a direction toward the opposite end. The internal ground plane is configured to overlap an approximate entirety of the lengths of the exposed end segments of the electrical wires when the exposed end segments are mounted to the mounting pads.

### BRIEF DESCRIPTION OF THE DRAWINGS

FIG. 1 is a perspective view of an exemplary embodiment a circuit board and wire assembly.

FIG. 2 is a perspective view of an exemplary embodiment of a circuit board of the circuit board and wire assembly shown in FIG. 1 illustrating an upper side of the circuit board.

FIG. 3 is a perspective view of the circuit board shown in FIG. 2 illustrating a lower side of the circuit board.

FIG. 4 is a cross-sectional view of the circuit board and wire assembly 10 shown in FIG. 1 taken along line 4-4 of FIG. 1.

FIG. 5 is a perspective view of an exemplary embodiment of an electrical connector with which the circuit board and wire assembly shown in FIGS. 1 and 4 may be used.

### DETAILED DESCRIPTION OF THE INVENTION

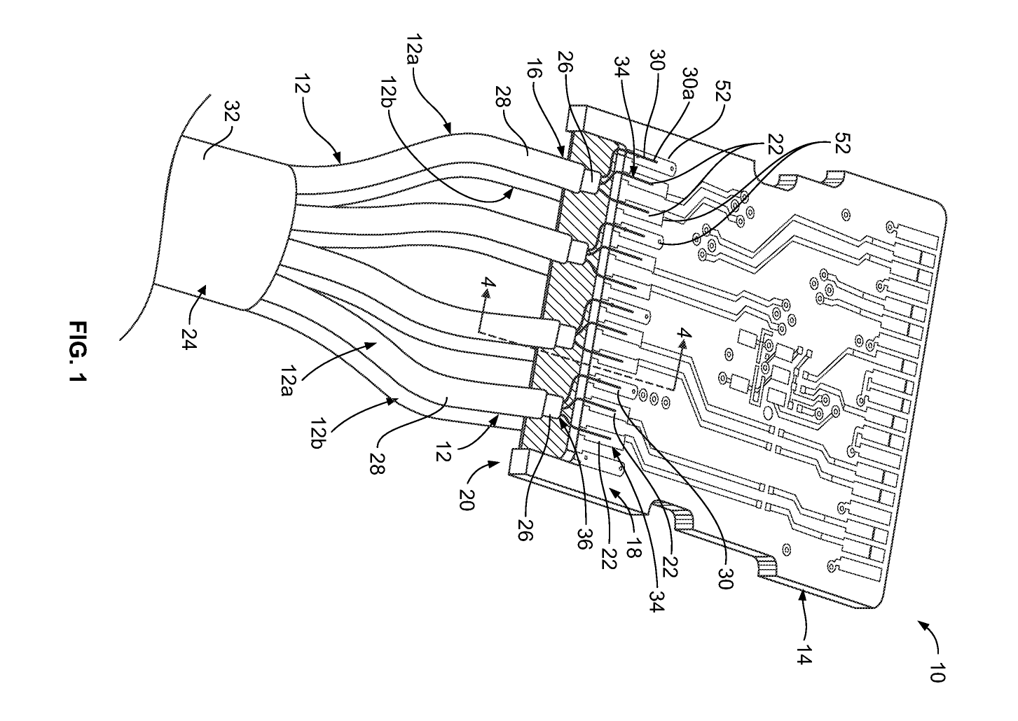

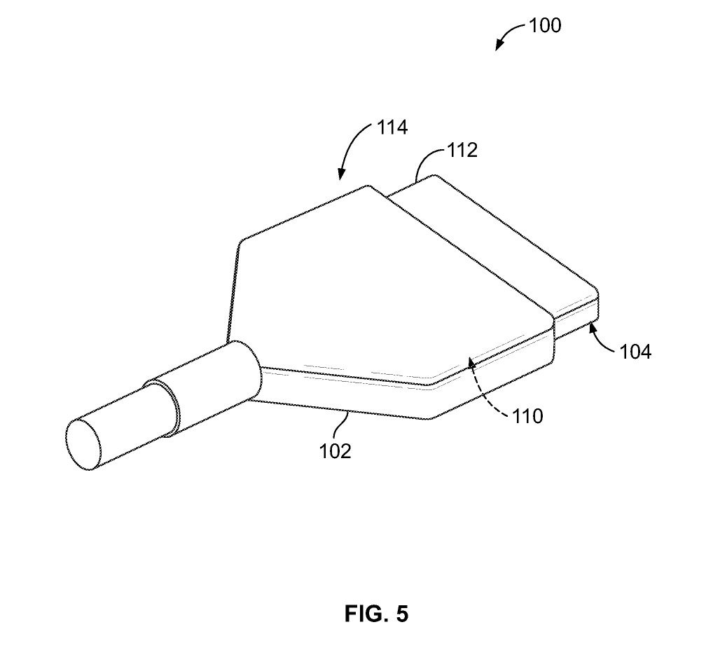

FIG. 1 is a perspective view of an exemplary embodiment of a circuit board and wire assembly 10. The assembly 10 includes electrical wires 12 and a circuit board 14 that terminates ends 16 of the electrical wires 12. The assembly 10 may be a component of any larger electrical component, system, and/or the like, such as, but not limited to, an electrical connector and/or the like. One example of an electrical connector within which the circuit board and wire assembly 10 may be used is a high-speed input/output (I/O) connector, such as, but not limited to, the I/O connector 100 shown in FIG. 5. The electrical wires 12 may electrically connect the circuit board 14 to any electrical component(s). In other words, ends (not shown) of the electrical wires 12 that are opposite the ends 16 may terminate any other electrical component(s).

In the exemplary embodiment, the electrical wires 12 include electrical wires 12a that are terminated to an upper side 18 of the circuit board 14, and electrical wires 12b that are terminated to a lower side 20 of the circuit board 14. Each electrical wire 12 includes one or more electrical signal conductors 22. Each electrical wire 12 may include any number of electrical signal conductors 22, which may be arranged in any arrangement relative to each other. In the exemplary embodiment, each electrical wire 12 includes two electrical signal conductors 22 that are arranged side-by-side, such that each electrical wires 12 is what is commonly referred to as a “twinax cable” or a “twin axial cable”. The electrical wires 12 may include differential signal pairs of electrical signal conductors 22. A differential signal pair of electrical signal conductors 22 is optionally contained within the same electrical wire 12. In the exemplary embodiment, each electrical wire 12 includes a differential signal pair of electrical signal conductors 22. Any number of electrical wires 12 may be terminated to the circuit board 14. Some or all of the electrical wires 12 may be grouped together in a cable. In the exemplary embodiment, the electrical wires 12 are grouped together in a single cable 24. But, any number of cables 24 may be terminated to the circuit board 14, each of which may include any number of electrical wires 12. The electrical wires 12a may be referred to herein as “upper electrical wires”, while the electrical wires 12b may be referred to herein as “lower electrical wires”.

The exemplary structure of the electrical wires 12 will now be described. In the exemplary embodiment, each electrical wire 12 includes the differential signal pair of electrical signal conductors 22. The electrical signal conductors 22 of each electrical wire 12 are surrounded, and separated, by an insulating member 26 of the electrical wire 12. The insulating member 26 may be a single member that surrounds both electrical signal conductors 22, or may be two discrete members that surround corresponding electrical signal conductors 22 of the electrical wire 12. Optionally, an electrically conductive shield 28 extends around the insulating member 26 of one or more of the electrical wires 12. One or more of the electrical wires 12 optionally includes a drain wire 30. In the exemplary embodiment, a cable jacket 32 surrounds the electrical wires 12 to group the electrical wires 12 within the cable 24.

As can be seen in FIG. 1, at the ends 16 of the electrical wires 12, the electrical signal conductors 22 include exposed end segments 34 that extend lengths outward from ends 36 of the insulating members 26. The exposed end segments 34 are thus exposed from the insulating members 26. The exposed end segments 34 enable the electrical wires 12, and specifically the electrical signal conductors 22, to be mounted to mounting pads 52 of the circuit board 14, for example using solder or an electrically conductive adhesive.

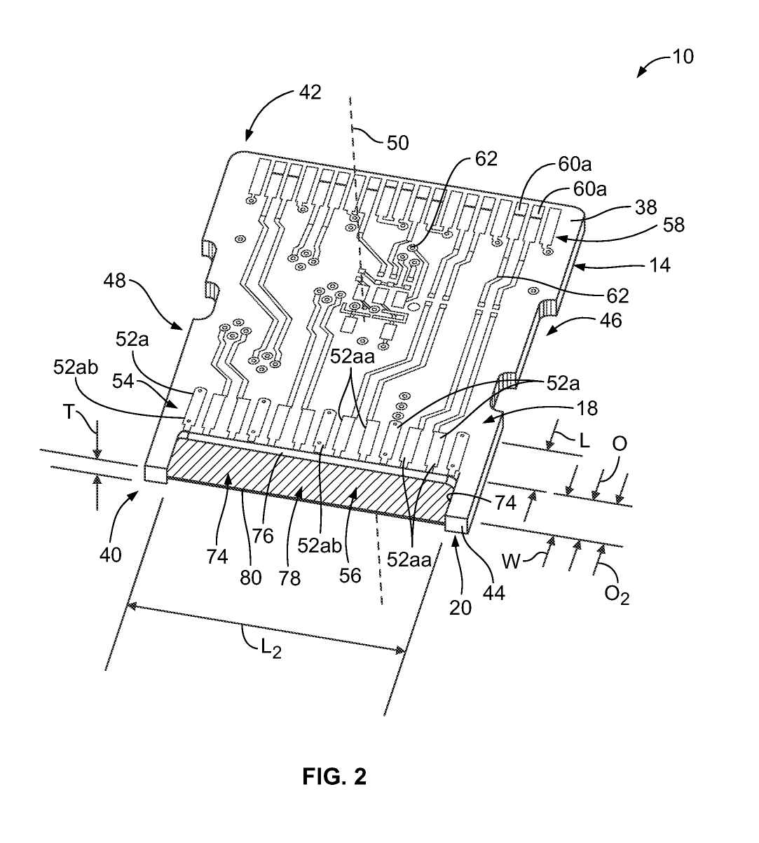

FIG. 2 is a perspective view of an exemplary embodiment of the circuit board 14 illustrating the upper side 18 of the circuit board 14. The circuit board 14 includes a substrate 38 that includes the upper and lower sides 18 and 20, respectively. The substrate 38 extends from a mounting end 40 to an opposite end 42. The mounting end 40 includes a mounting edge 44. Optionally, the opposite end 42 is a mating end wherein the circuit board 14 mates with a mating connector (not shown). The substrate 38 extends from an end 46 to an opposite end 48. The substrate 38 extends a thickness T along a thickness axis 50 from the upper side 18 to the lower side 20. The upper and lower sides 18 and 20 may each be referred to herein as a “side” and/or an “opposite side”.

The circuit board 14 includes mounting pads 52 to which the electrical wires 12 are terminated. The upper side 18 of the substrate 38 includes a mounting region 54 at which the electrical wires 12a are terminated to the circuit board 14. Specifically, the circuit board 14 includes mounting pads 52a that extend on the upper side 18 of the substrate 38 within the mounting region 54. In the exemplary embodiment, the mounting pads 52a are arranged in a row that extends a length along the upper side 18 of the substrate 38 between the ends 46 and 48. The mounting pads 52a may have any other arrangement, pattern, and/or the like along the upper side 18 of the substrate 38. The mounting pads 52a may be referred to herein as “upper mounting pads”.

The mounting pads 52a include signal mounting pads 52aa and ground mounting pads 52ab. As will be described below, electrical signal conductors 22 of the electrical wires 12a are mounted to the signal mounting pads 52aa, while drain wires 30a of the electrical wires 12a are mounted to the ground mounting pads 52ab. The ground mounting pads 52ab may be electrically connected to a ground plane 56 of the circuit board 14. The mounting pads 52a extend lengths L along the substrate 38.

As can be seen in FIG. 2, the mounting region 54 is offset O along the mounting end 40 in a direction toward the opposite end 42. In the exemplary embodiment, the mounting region 54 is offset O along the mounting end 40 from the mounting edge 44 in a direction toward the opposite end 42. The mounting region 54 may be offset O along the mounting end 40 toward the opposite end 42 by any amount. For example, the mounting region 54 may be offset O from the mounting edge 44 in a direction toward the opposite end 42 by any amount. One example of the offset O of the mounting region 54 includes offsetting the mounting region 54 from the mounting edge 44 in a direction toward the opposite end 42 by at least half of the value of the length L of one or more of the mounting pads 52a.

The circuit board 14 may be configured to mate with a mating connector. For example, the end 42 of the substrate 38 may define a card edge that is configured to mate with a complementary mating connector. In the exemplary embodiment, the upper side 18 of the substrate 38 includes a mating region 58 that defines a portion of the card edge that mates with the complementary mating connector. The circuit board 14 includes mating pads 60a that extend on the upper side 18 of the substrate 38 within the mating region 58. The mating pads 60a mate with corresponding mating contacts (not shown) of the complementary mating connector to establish an electrical connection between the circuit board 14 and the complementary mating connector. In the exemplary embodiment, the mating pads 60a are arranged in a row that extends a length along the upper side 18 of the substrate 38 between the ends 46 and 48. But, the mating pads 60a may have any other arrangement, pattern, and/or the like along the upper side 18 of the substrate 38.

The circuit board 14 may include one or more electrical traces 62 that electrically connect the signal mounting pads 52aa to corresponding mating pads 60a. In other words, the electrical traces 62 define electrical paths that extend along the substrate 38 from the signal mounting pads 52aa to the corresponding mating pads 60a. In the exemplary embodiment, the electrical traces 62 extend on the upper side 18 of the substrate 38. But, in addition or alternatively, one or more of the electrical traces 62 may be an internal trace that extends within the thickness T of the substrate 38 between the upper side 18 and the lower side 20.

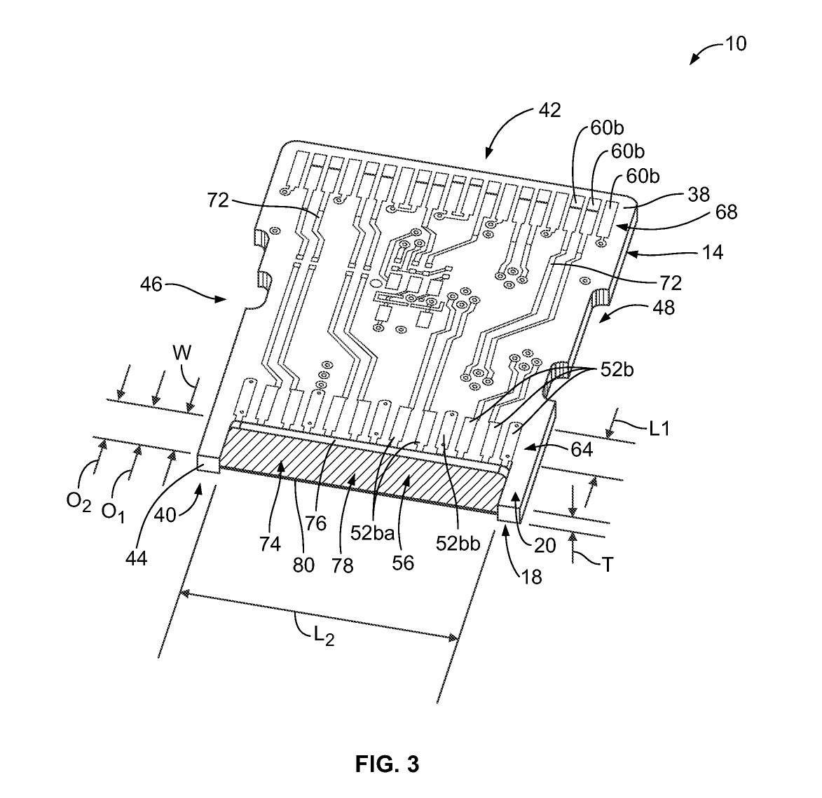

FIG. 3 is a perspective view of the circuit board 14 illustrating the lower side 20 of the circuit board 14. The lower side 20 of the substrate 38 includes a mounting region 64 at which the lower electrical wires 12b are terminated to the circuit board 14. Specifically, the mounting pads 52 include mounting pads 52b that extend on the lower side 20 of the substrate 38 within the mounting region 64. In the exemplary embodiment, the mounting pads 52b are arranged in a row that extends a length along the lower side 20 of the substrate 38 between the ends 46 and 48. But, the mounting pads 52b may have any other arrangement, pattern, and/or the like along the lower side 20 of the substrate 38. The mounting pads 52b may be referred to herein as “lower mounting pads”.

The mounting pads 52b include signal mounting pads 52ba and ground mounting pads 52bb. Electrical signal conductors 22 of the electrical wires 12b are mounted to the signal mounting pads 52ba, while drain wires 30 (not shown) of the electrical wires 12b are mounted to the ground mounting pads 52bb. The ground mounting pads 52bb may be electrically connected to the ground plane 56 of the circuit board 14. The mounting pads 52b extend lengths L₁ along the substrate 38.

The mounting region 64 is offset O₁ along the mounting end 40 in a direction toward the opposite end 42. In the exemplary embodiment, the mounting region 64 is offset O₁ along the mounting end 40 from the mounting edge 44 in a direction toward the opposite end 42. The mounting region 64 may be offset O₁ along the mounting end 40 toward the opposite end 42 by any amount. For example, the mounting region 64 may be offset O₁ from the mounting edge 44 in a direction toward the opposite end 42 by any amount. An exemplary offset O₁ of the mounting region 64 includes offsetting the mounting region 64 from the mounting edge 44 in a direction toward the opposite end 42 by at least half of the value of the length L₁ of one or more of the mounting pads 52b.

In embodiments wherein the circuit board 14 is configured to mate with a complementary mating connector, the lower side 20 of the substrate 38 includes a mating region 68. Mating pads 60b extend on the lower side 20 of the substrate 38 within the mating region 68. In the exemplary embodiment, the mating pads 60b are arranged in a row that extends a length along the lower side 20 of the substrate 38 between the ends 46 and 48. But, the mating pads 60b may have any other arrangement, pattern, and/or the like along the lower side 20 of the substrate 38. Electrical traces 72 may be provided to electrically connect the signal mounting pads 52ba to corresponding mating pads 60b. In the exemplary embodiment, the electrical traces 72 extend on the lower side 20 of the substrate 38. But, in addition or alternatively, one or more of the electrical traces 72 may be an internal trace that extends within the thickness T of the substrate 38 between the upper side 18 and the lower side 20.

Referring now to FIGS. 2 and 3, the circuit board 14 includes the ground plane 56 that is held by the substrate 38. In the exemplary embodiment, the ground plane 56 is an internal layer of the circuit board 14 that extends within the thickness T of the circuit board 14 between the upper side 18 and the lower side 20. The exemplary embodiment of the ground plane 56 defines an internal layer of the circuit board 14. In addition or alternatively, the circuit board 14 may include a ground plane (not shown) that extends on the upper side 18 of the substrate 38 and/or may include a ground plane (not shown) that extends on the lower side 20 of the substrate 38. The circuit board 14 may include any number of ground planes. Moreover, the circuit board 14 may include any number of layers. The ground plane 56 may be referred to herein as an “internal ground plane”.

In the exemplary embodiment, the ground plane 56 extends along an approximate entirety of the substrate 38 from the mounting end 40 to the opposite end 42, and extends along an approximate entirety of the substrate from the end 46 to the end 48. But, the ground plane 56 may extend only partially between the ends 40 and 42 and/or only partially between the ends 46 and 48.

The substrate 38 includes an optional recess 74 that extends into the mounting end 40 of the substrate 38. The recess 74 extends into the mounting end 40 in a direction toward the opposite end 42. Each of the mounting regions 54 and 56 extends on the respective side 18 and 20 of the substrate 38 between the recess 74 and the opposite end 42. The recess 74 is defined by a recessed edge 76 of the substrate 38 that is offset O₂ from the mounting edge 44 in a direction toward the opposite end 42. The mounting pads 52a and 52b extend on the respective sides 18 and 20 of the substrate 38 proximate the recessed edge 76, as shown in FIGS. 2 and 3, respectively.

The recess 74 extends a length L₂ and a width W. The recessed edge 76 may be offset O₂ along the mounting end 40 toward the opposite end 42 by any amount. In the exemplary embodiment, the recessed edge 76 is offset O₂ from the mounting edge 44 in a direction toward the opposite end 42. One example of the offset O₂ of the recessed edge 76 includes offsetting the recessed edge 76 from the mounting edge 44 in a direction toward the opposite end 42 by at least half of the value of the length L and/or L₁ of one or more of the mounting pads 52. Although shown as having a generally rectangular shape, the recess 74 may additionally or alternatively include any other shape. The recess 74 may have any size. For example, the length L₂ and width W of the recess 74 may each have any value.

In embodiments wherein the substrate 38 includes the recess 74, the ground plane 56 includes a recess segment 78 that extends within the recess 74. The recess segment 78 is exposed within the recess 74, as can be seen in FIGS. 2 and 3. The recess segment 78 extends to an edge 80, which in the exemplary embodiment is aligned with the mounting edge 44 of the substrate 38. In the exemplary embodiment, the recess segment 78 of the ground plane 56 extends along an approximate entirety of the width W and an approximate entirety of the length L₂ of the recess 74. In other words, in the exemplary embodiment, the recess segment 78 fills an approximate entirety of the width W and an approximate entirety of the length L₂ of the recess 74. But, the recess segment 78 may extend along only a portion the length L₂ and/or along only a portion of the width W of the recess 74.

As described above, the mounting region 54, the mounting region 64, and the recessed edge 76 are each described as being offset O, O₁, and O₂, respectively, from the mounting edge 44 of the substrate 38. In some alternative embodiments, the substrate 38 does not include the mounting edge 44. In other words, at least a portion of the width W of the recess 74 extends along an approximate entirety of the substrate from the end 46 to the end 48 and the ground plane 56 extends outward from the substrate 38 in a direction away from the end 42. Thus, instead of the mounting edge 44 of the substrate 38 defining a mounting edge of the circuit board 14, the edge 80 of the ground plane 56 defines a mounting edge of the circuit board 14. In such embodiments wherein the substrate 38 does not include the mounting edge 44, the offsets O, O₁, and O₂ of the mounting region 54, the mounting region 64, and the recessed edge 76, respectively, are considered to be taken from the edge 80 of the ground plane 56.

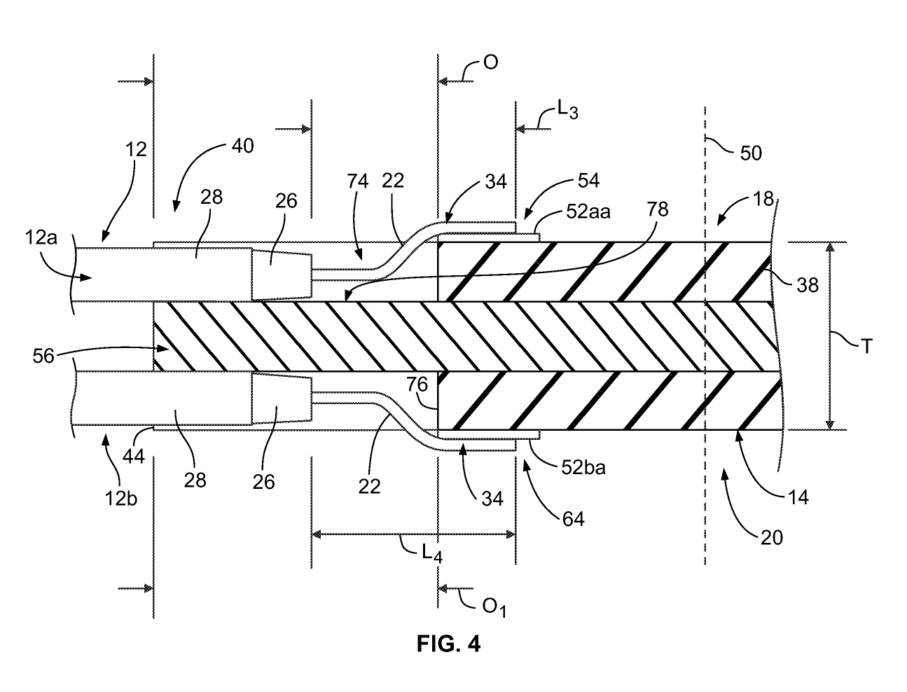

FIG. 4 is a cross-sectional view of the circuit board and wire assembly 10 taken along line 4-4 of FIG. 1. FIG. 4 illustrates the electrical wires 12 being terminated to the circuit board 14. The exposed end segments 34 of the electrical signal conductors 22 of the upper and lower electrical wires 12a and 12b, respectively, are mounted to the corresponding signal mounting pads 52aa and 52ba of the circuit board 14. Each of the exposed end segments 34 may be mounted to the corresponding signal mounting pad 52aa or 52ba using any suitable method, structure, attachment means, and/or the like that electrically connects the exposed segments 34 to the corresponding signal mounting pad 52aa or 52ba, such as, but not limited to, using solder, using an electrically conductive adhesive, and/or the like.

As can be seen in FIG. 4, the exposed end segments 34 of the electrical signal conductors 22 of the upper electrical wires 12a overlap the recess segment 78 of the ground plane 56 within the recess 74. The exposed end segments 34 of the electrical signal conductors 22 of the lower electrical wires 12b overlap the recess segment 78 of the ground plane 56 within the recess 74. In the exemplary embodiment, the ground plane 56 overlaps an approximate entirety of lengths L₃ and L₄ of the exposed end segments 34 of the upper and lower electrical wires 12a and 12b, respectively. But, the ground plane 56 may overlap any amount of the lengths L₃ and L₄ of each of the exposed end segments 34 of the upper and lower electrical wires 12a and 12b, respectively.

The ground plane 56 extends between the exposed end segments 34 of the lower electrical wires 12b and the exposed end segments 34 of the upper electrical wires 12a. Specifically, the recess segment 78 of the ground plane 56 extends between the exposed end segments 34 of the upper electrical wires 12a and the exposed end segments 34 of the lower electrical wires 12b along the thickness T, and thus along the thickness axis 50, of the substrate 38. In the exemplary embodiment, the ground plane 56 defines a perpendicular bisector that extends between the exposed end segments 34 of the upper and lower electrical wires 12a and 12b, respectively, along the thickness T. In the exemplary embodiment, the ground plane 56 extends between the exposed end segments 34 of the upper electrical wires 12a and the exposed end segments 34 of the lower electrical wires 12b along an approximate entirety of lengths L₃ and L₄, respectively, of the exposed end segments 34 of the upper electrical wires 12a and the exposed end segments 34 of the lower electrical wires 12b. But, the ground plane 56 may extend between any amount of the lengths L₃ and L₄ of the exposed end segments 34 of the upper and lower electrical wires 12a and 12b, respectively.

As described above, in the exemplary embodiment, the upper electrical wires 12a include differential signal pairs of the electrical signal conductors 22 and the lower electrical wires 12b include differential signal pairs of the electrical signal conductors 22. The ground plane 56 extends between the differential signal pairs of the upper electrical wires 12a and the differential signal pairs of the lower electrical wires 12b along the thickness T of the substrate 38. The differential signal pairs of the upper electrical wires 12a may be referred to herein as “upper differential signal pairs”, while the differential signal pairs of the lower electrical wires 12b may be referred to herein as “lower differential signal pairs”.

Optionally, the insulating members 26 of the upper electrical wires 12a and/or the insulating members 26 of the lower electrical wires 12b overlap the recess segment 78 of the ground plane 56 within the recess 74, for example as can be seen in FIG. 4. The ground plane 56 may extend between the insulating members 26 of the upper and lower electrical wires 12a and 12b, respectively, along the thickness T of the substrate 38. The shields 28 of the upper electrical wires 12a and/or the shields 28 of the lower electrical wires 12b optionally overlap the recess segment 78 of the ground plane 56 within the recess 74. When both the shields 28 of the upper electrical wires 12a and the shields 28 of the lower electrical wires 12b overlap the recess segment 78, the ground plane 56 extends between the shields 28 of the upper and lower electrical wires 12a and 12b, respectively, along the thickness T of the substrate 38.

The ground plane 56 shields the exposed end segments 34 of the electrical signal conductors 22 of the upper electrical wires 12a from the exposed end segments 34 of the electrical signal conductors 22 of the lower electrical wires 12b. The shielding provided by the ground plane 56 may facilitate reducing crosstalk between the exposed end segments 34 of the upper electrical wires 12a and the exposed end segments 34 of the electrical signal conductors 22 of the lower electrical wires 12b. In the exemplary embodiment, the ground plane 56 shields the exposed end segments 34 of differential signal pairs of the upper electrical wires 12a from the exposed end segments 34 of the differential signal pairs of the lower electrical wires 12b. The shielding provided by the ground plane 56 may thus facilitate reducing crosstalk between the exposed end segments 34 of the differential signal pairs of the upper electrical wires 12a and the exposed end segments 34 of the differential signal pairs of the lower electrical wires 12b. It should be understood that in embodiments wherein the substrate 38 does not include the recess 74, the recess segment 78 of the ground plane 56 will still be overlapped by, and extend between, the exposed end segments 34 of the upper and lower electrical wires 12a and 12b, respectively, because of the offsets O and O₁ of the mounting regions 54 and 64, respectively, that are described and/or illustrated herein.

The shield 28 of one or more of the upper electrical wires 12a and/or the shield 28 of one or more of the lower electrical wires 12b is optionally directly electrically connected to the recess segment 78 of the ground plane 56. For example, the shield 28 of an upper electrical wire 12a and/or the shield 28 of a lower electrical wire 12b may be engaged with the recess segment 78 of the ground plane 56, may be soldered to the recess segment 78 of the ground plane 56, and/or may be attached to the recess segment 78 of the ground plane 56 using an electrically conductive adhesive. Optionally, the drain wire 30a (FIG. 1) of one or more of the upper electrical wires 12a and/or the drain wire 30 of one or more of the lower electrical wires 12b is directly electrically connected to the recess segment 78 of the ground plane 56. For example, the drain wire 30a of an upper electrical wire 12a and/or the drain wire 30 of a lower electrical wire 12b may be engaged with the recess segment 78 of the ground plane 56, may be soldered to the recess segment 78 of the ground plane 56, and/or may be attached to the recess segment 78 of the ground plane 56 using an electrically conductive adhesive. In the exemplary embodiment, and as can be seen in FIG. 1, the drain wires 30a of the electrical wires 12a are mounted to the ground mounting pads 52ab.

FIG. 5 is a perspective view of an exemplary embodiment of an electrical connector 100 with which the circuit board and wire assembly 10 (FIG. 1) may be used. The electrical connector 100 includes a housing 102, an insert 104, and the circuit board 14 (FIGS. 1-4). The electrical wires 12, the assembly 10, and the cable 24 are not shown in FIG. 5 for clarity. The housing 102 includes an interior compartment 110 within which the assembly 10 and the insert 104 are held. The insert 104 includes an extension 112 that extends outward from a front 114 of the housing 102.

The insert 104 holds the circuit board 14 such that the end 42 (FIGS. 1-4) of the substrate 38 (FIGS. 1-4) extends within the extension 112 for mating with a complementary mating connector (not shown). Specifically, the end 42 of the substrate 38 defines a card edge that is configured to mate with the complementary mating connector. The circuit board 14 includes the mating pads 60 (FIGS. 1-3) that mate with corresponding mating contacts (not shown) of the complementary mating connector to establish an electrical connection between the electrical connector 100 and the complementary mating connector.

The electrical wires 12 are shown and described herein as being twinax cables that include two electrical signal conductors 22 that operate as a differential signal pair. However, the subject matter described and/or illustrated herein is not limited to twin axial cables, nor cables having two electrical conductors that operate as a differential signal pair. Rather, the subject matter described and/or illustrated herein may be used with any type of electrical wire having any number of electrical signal conductors, whether or not the electrical wire includes one or more differential signal pairs of electrical signal conductors, one or more insulating members, a cable jacket, one or more ground shields, one or more drain wires, and/or the like.

As used herein, the term “circuit board” is intended to mean any electric circuit in which the electrical conductors have been printed or otherwise deposited in predetermined patterns on an electrically insulating substrate. The circuit board 14 may be a flexible member or a rigid member. The circuit board 14 may be fabricated from and/or may include any material(s), such as, but not limited to, ceramic, epoxy-glass, polyimide (such as, but not limited to, Kapton® and/or the like), organic material, plastic, polymer, and/or the like. In some embodiments, the circuit board 14 is a rigid member fabricated from epoxy-glass.

The embodiments described and/or illustrated herein may provide a circuit board and wire assembly that experiences less crosstalk between electrical wires that are terminated to the circuit board.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter described and/or illustrated herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A circuit board comprising:
a substrate extending from a mounting end to an opposite end, the substrate extending a thickness from an upper side to a lower side, the substrate comprising a recess that extends into the mounting end in a direction toward the opposite end; and
an internal ground plane held by the substrate such that the internal ground plane extends within the thickness of the substrate, the internal ground plane comprising a recess segment that extends, and is exposed, within the recess.

2. The circuit board of claim 1, wherein the mounting end comprises a mounting edge, the recess being defined by a recessed edge that is offset from the mounting edge along the substrate in a direction toward the opposite end.

3. The circuit board of claim 1, wherein at least one of the upper side or the lower side of the substrate comprises a mounting region that extends between the recess and the opposite end, the circuit board comprising contact pads that extend on the substrate within the mounting region.

4. The circuit board of claim 1, wherein the mounting end comprises a mounting edge, the recess being defined by a recessed edge that is offset from the mounting edge along the substrate in a direction toward the opposite end, the circuit board comprising mounting pads that extend on at least one of the upper or lower sides of the substrate proximate the recessed edge.

5. The circuit board of claim 1, wherein the circuit board is configured to terminate electrical wires that include insulating members, the recess segment of the internal ground plane being configured to be overlapped by the insulating members within the recess when the electrical wires are terminated to the circuit board.

6. The circuit board of claim 1, wherein the circuit board is configured to terminate electrical wires that include insulating members and electrical conductors having exposed end segments that extend outward from the insulating members, the recess segment of the internal ground plane being configured to be overlapped by the exposed end segments within the recess when the electrical wires are terminated to the circuit board.

7. The circuit board of claim 1, wherein the recess segment of the internal ground plane is configured to be directly electrically connected to at least one of a shield or a drain wire of an electrical wire that is terminated to the circuit board.

8. The circuit board of claim 1, wherein the opposite end of the substrate comprises mating pads that are configured to mate with a mating connector.

9. A circuit board and wire assembly comprising:
upper and lower electrical wires having insulating members and electrical signal conductors that include exposed end segments that extend lengths outward from the insulating members; and
a circuit board comprising:
a substrate extending a thickness from an upper side to a lower side;
upper mounting pads extending on the upper side of the substrate, the exposed end segments of the upper electrical wires being terminated to the upper mounting pads;
lower mounting pads extending on the lower side of the substrate, the exposed end segments of the lower electrical wires being terminated to the lower mounting pads; and
an internal ground plane held by the substrate such that the internal ground plane extends within the thickness of the substrate, wherein the internal ground plane extends between the exposed end segments of the upper electrical wires and the exposed end segments of the lower electrical wires along an approximate entirety of the lengths of the exposed end segments of the upper and lower electrical wires.

10. The assembly of claim 9, wherein the substrate extends the thickness along a thickness axis, the internal ground plane defining a perpendicular bisector that extends between the exposed end segments of the upper and lower electrical wires along the thickness axis.

11. The assembly of claim 9, wherein the internal ground plane extends between the insulating members of the upper electrical wires and the insulating members of the lower electrical wires along the thickness of the substrate.

12. The assembly of claim 9, wherein the upper electrical wires include upper differential signal pairs of electrical conductors, the lower electrical wires comprising lower differential signal pairs of electrical conductors, the internal ground plane extending between the upper differential signal pairs and the lower differential signal pairs along the thickness of the substrate.

13. The assembly of claim 9, wherein the substrate extends from a mounting end to an opposite end, the substrate comprising a recess that extends into the mounting end in a direction toward the opposite end, the internal ground plane comprising a recess segment that extends, and is exposed, within the recess.

14. The assembly of claim 9, wherein the internal ground plane is at least one of:
engaged with at least one of a shield or a drain wire of at least one of the electrical wires; or
soldered to at least one of a shield or a drain wire of at least one of the electrical wires.

15. The assembly of claim 9, wherein the upper and lower electrical wires comprise twinax cables.

16. A circuit board for terminating electrical wires having insulating members and exposed end segments that extend lengths outward from the insulating members, the circuit board comprising:
a substrate extending from a mounting end to an opposite end, the substrate having a side that includes a mounting region, the substrate extending a thickness from the side to an opposite side; and
mounting pads extending on the side of the substrate within the mounting region; and
an internal ground plane held by the substrate such that the internal ground plane extends within the thickness of the substrate, the mounting region of the substrate being offset along the mounting end in a direction toward the opposite end, the internal ground plane being configured to overlap an approximate entirety of the lengths of the exposed end segments of the electrical wires when the exposed end segments are mounted to the mounting pads.

17. The circuit board of claim 16, wherein the internal ground plane is configured to overlap the insulating segments of the electrical wires when the exposed end segments of the electrical wires are mounted to the mounting pads.

18. The circuit board of claim 16, wherein the mounting pads extend lengths along the substrate, the mounting region of the substrate being offset toward the opposite end by at least half of the value of the lengths of the mounting pads.

19. The circuit board of claim 16, wherein the substrate comprises a recess that extends into the mounting end in a direction toward the opposite end, the mounting region extending between the recess and the opposite end, the internal ground plane comprising a recess segment that extends, and is exposed, within the recess.

20. The circuit board of claim 16, wherein the internal ground plane is configured to be at least one of:
engaged with at least one of a shield or a drain wire of at least one of the electrical wires; or
soldered to at least one of a shield or a drain wire of at least one of the electrical wires.
